(19) United States
(12) Patent Application Publication
(10) Pub. No.: US 2025/0309062 A1
(43) Pub. Date: Oct. 2, 2025

(54) SEMICONDUCTOR DEVICE

(71) Applicant: Rohm Co., Ltd., Kyoto-shi (JP)

(72) Inventors: Yoshimasa FUJISADA, Kyoto-shi (JP); Koshun SAITO, Kyoto-shi, Kyoto (JP)

(21) Appl. No.: 19/193,464

(22) Filed: Apr. 29, 2025

Related U.S. Application Data
(63) Continuation of application No. PCT/JP2023/037902, filed on Oct. 19, 2023.

(30) Foreign Application Priority Data
Nov. 4, 2022 (JP) 2022-177196

(51) Int. Cl. H01L 23/495; H01L 23/00; H01L 23/31

(52) U.S. Cl. CPC H01L 23/49503; H01L 23/3107; H01L 24/32; H01L 24/40; H01L 24/48; H01L 24/73; H01L 2224/32245; H01L 2224/40245; H01L 2224/48245; H01L 2224/73221; H01L 2224/73263; H01L 2224/73265

(57) ABSTRACT

A semiconductor device comprises a die pad having a penetration portion that penetrates in a first direction, a semiconductor element bonded to the die pad and a sealing resin covering the semiconductor element, the sealing resin having an attachment portion that penetrates in the first direction and is surrounded by the penetration portion as viewed in the first direction. The die pad includes a first portion having a reverse surface that faces the first direction, and a second portion having the penetration portion and connected to the first portion. The second portion is offset on one side of a second direction with respect to the first portion. The reverse surface is exposed from the sealing resin. The second portion is covered with the sealing resin.

### TECHNICAL FIELD

The present disclosure relates to a semiconductor device.

### BACKGROUND

JP-A-2018-014490 discloses an example of a semiconductor device having a first semiconductor element and a first lead that conducts to said first semiconductor element. The first semiconductor element is a switching element such as a MOSFET. The first lead includes a first pad to which the first semiconductor element is conductively bonded and a first terminal connected to the first pad. By having a DC voltage applied to the first terminal and driving the first semiconductor element, the DC power can be converted to AC power.

The semiconductor device disclosed in JP-A-2018-014490 further comprises a sealing resin covering the first semiconductor element. The sealing resin has a through hole in the resin that penetrates through the first pad in the thickness direction. When the semiconductor device is mounted on a heat sink, a fastening member such as a bolt is inserted through the resin through hole. The pad reverse surface of the first pad surrounds the resin through hole in the thickness direction. The pad reverse surface is covered with sealing resin. Here, the pad reverse surface may be exposed from the sealing resin in order to suppress the degradation of the heat dissipation of the semiconductor device in question. In this case, the semiconductor device mounted on the heat sink has a relatively short creepage distance from the reverse surface of the pad to the fastening member. This may result in a decrease in the insulation withstand voltage of the semiconductor device.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, in which the sealing resin is shown as transparent.

FIG. 4 is a bottom view of the semiconductor device shown in FIG. 1.

FIG. 5 is a front view of the semiconductor device shown in FIG. 1.

FIG. 6 is a cross-sectional view taken along a line VI-VI in FIG. 3.

FIG. 7 is a cross-sectional view taken along a line VII-VII in FIG. 3.

FIG. 8 is a cross-sectional view taken along a line VIII-VIII in FIG. 3.

FIG. 9 is a partially enlarged view of FIG. 6.

FIG. 10 is a plan view of a semiconductor device according to a second embodiment of the present disclosure, in which the sealing resin is shown as transparent.

FIG. 11 is a bottom view of the semiconductor device shown in FIG. 10.

FIG. 12 is a cross-sectional view taken along a line XII-XII in FIG. 10.

FIG. 13 is a cross-sectional view taken along a line XIII-XIII in FIG. 10.

FIG. 14 is a plan view of a semiconductor device according to a third embodiment of the present disclosure.

FIG. 15 is a plan view corresponding to FIG. 14, in which the sealing resin is shown as transparent.

FIG. 16 is a bottom view of the semiconductor device shown in FIG. 14.

FIG. 17 is a cross-sectional view taken along a line XVII-XVII in FIG. 15.

FIG. 18 is a cross-sectional view taken along a line XVIII-XVIII in FIG. 15.

### MODE FOR CARRYING OUT THE INVENTION

The following describes modes for carrying out the present disclosure with reference to the accompanying drawings.

### First Embodiment

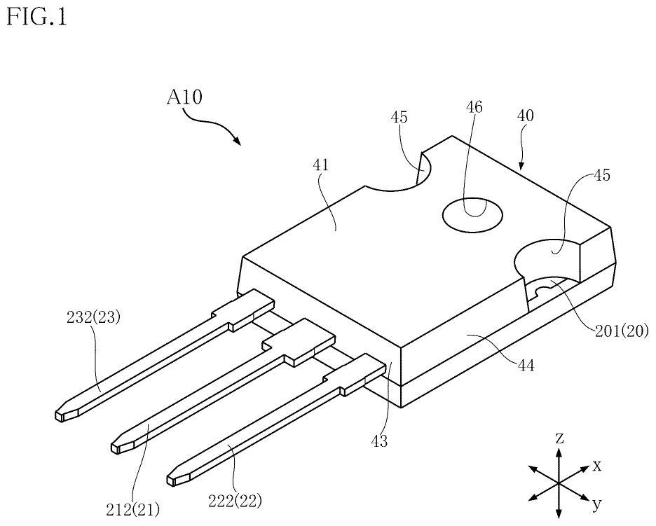

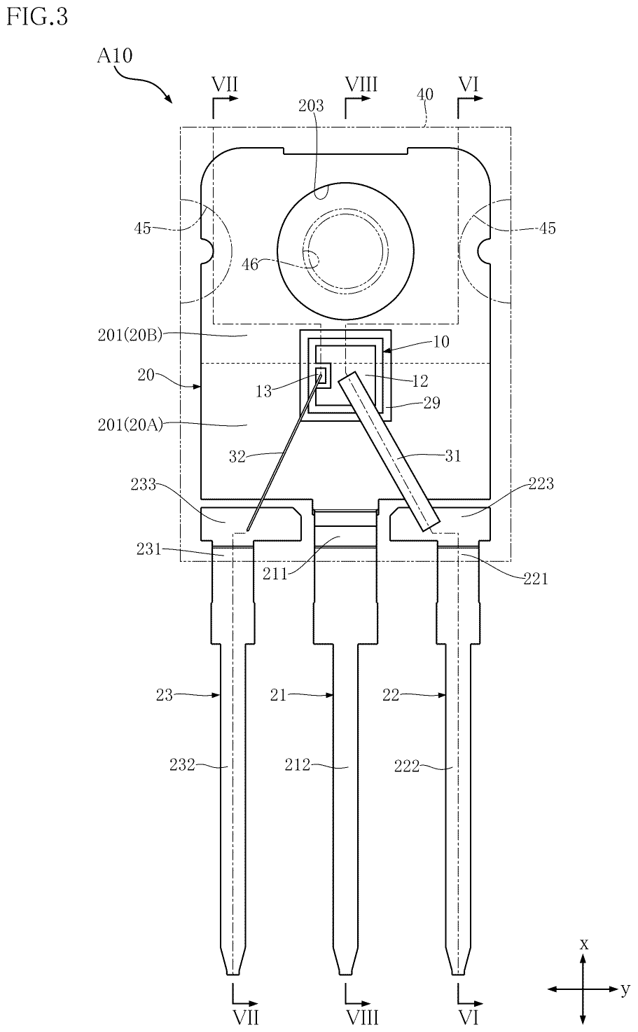

Based on FIGS. 1 to 9, a semiconductor device A10 according to a first embodiment of the present disclosure will be described. Generally, the semiconductor device A10 is used for power conversion circuits such as inverters. The package type of the semiconductor device A10 is TO (Transistor Outline). The semiconductor device A10 includes a semiconductor element 10, a die pad 20, a first lead 21, a second lead 22, a third lead 23, a conductive bonding layer 29, a conductive member 31, a wire 32, and a sealing resin 40. For convenience of understanding, in FIG. 3, the sealing resin 40 is shown as transparent. In FIG. 3, the sealing resin shown as transparent is shown as imaginary lines (double-dotted lines).

In the description of the semiconductor device A10, a normal direction of a mounting surface 201 of a die pad 20, which is described hereinafter, is referred to as a “first direction z”, for the sake of convenience. One example of a direction orthogonal to the first direction z is referred to as a “second direction x”. One example of a direction orthogonal to the first direction z and the second direction x is referred to as a “third direction y”.

The semiconductor element 10 is, for example, a MOSFET (Metal-Oxide-Semiconductor Field-Effect Transistors). Alternatively, the semiconductor element 10 may be a field effect transistor such as a MISFET (Metal-Insulator-Semiconductor Field-Effect Transistor) or a bipolar transistor such as an IGBT (Insulated Gate Bipolar Transistors). The semiconductor device A10 is described under the assumption that the semiconductor element 10 is an n-channel MOSFET having a vertical structure. The semiconductor element 10 includes a compound semiconductor substrate. The composition of the compound semiconductor substrate includes silicon carbide (SiC).

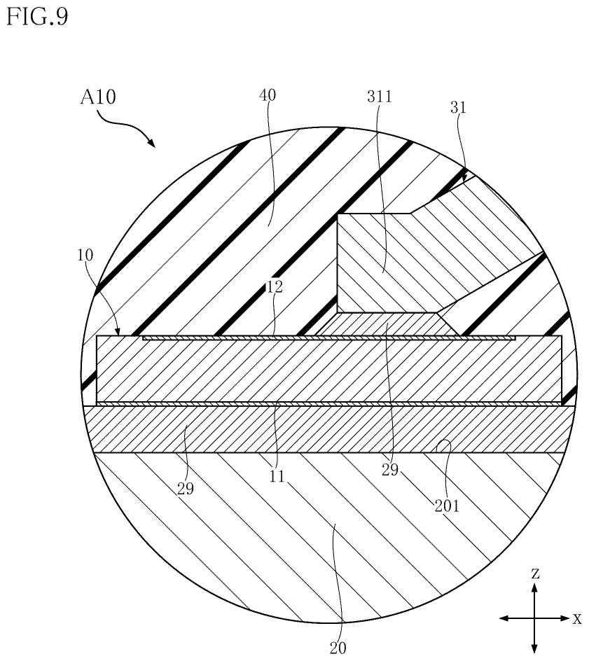

As shown in FIGS. 3 and 9, the semiconductor element 10 includes a first electrode 11, a second electrode 12, and a gate electrode 13.

As shown in FIG. 9, the first electrode 11 is disposed so as to face a mounting surface 201, which is described hereinafter, of the die pad 20 in the first direction z. A current flows through the first electrode 11, the current corresponding to the electric power prior to its conversion by the semiconductor element 10. In other words, the first electrode 11 corresponds to the drain electrode of the semiconductor element 10.

As shown in FIGS. 3 and 9, the second electrode 12 is located opposite to the first electrode 11 in the first direction z. A current flows through the second electrode 12, the current corresponding to the electric power after its conversion by the semiconductor element 10. In other words, the second electrode 12 corresponds to the source electrode of the semiconductor element 10.

As shown in FIG. 3, the gate electrode 13 is located on the same side as the second electrode 12 in the first direction z. A gate voltage to drive the semiconductor element 10 is applied to the gate electrode 13. As viewed in the first direction z, the area of the gate electrode 13 is smaller than that of the second electrode 12.

As shown in FIGS. 3 and 6 to 8, the die pad 20 is a conductive member on which the semiconductor element 10 is mounted. The die pad 20 is formed from a single lead frame, together with the first lead 21, the second lead 22, and the third lead 23. The lead frame contains copper (Cu) or a copper alloy. Hence, the composition of each of the die pad 20, the first lead 21, the second lead 22, and the third lead 23 includes copper. As shown in FIGS. 6 to 8, the die pad 20 has a mounting surface 201 and a reverse surface 202. The mounting surface 201 faces the semiconductor element 10 in the first direction z. The mounting surface 201 is covered with the sealing resin 40. The reverse surface 202 faces the side opposite to the mounting surface 201 in the first direction z. The reverse surface 202 is plated with tin (Sn), for example. The reverse surface 202 is exposed from the sealing resin 40.

As shown in FIGS. 3, 4, and 6 to 8, the die pad 20 includes a first portion 20A and a second portion 20B connected to the first portion 20A. As viewed in the first direction z, the second portion 20B is offset on the x1 side of the second direction x with respect to the first portion 20A. The second portion 20B is covered with the sealing resin 40. Each of the first portion 20A and the second portion 20B includes the mounting surface 201. The first portion 20A includes the reverse surface 202. The second portion 20B has a penetration portion 203. The penetration portion 203 penetrates the second portion 20B in the first direction z. The penetration portion 203 is circular as viewed in the first direction z. In the semiconductor device A10, a first dimension t1 in the first direction z of the first portion 20A is greater than a second dimension t2 in the first direction z of the second portion 20B. In the semiconductor device A10, a dimension in the second direction x of the second portion 20B is greater than a dimension in the second direction x of the reverse surface 202.

As shown in FIGS. 6 to 8, the conductive bonding layer 29 bonds the die pad 20 and the semiconductor element 10. As shown in FIG. 9, the first electrode 11 of the semiconductor element 10 is conductively bonded to the mounting surface 201 of the die pad 20 via the conductive bonding layer 29. Hence, the first electrode 11 is electrically connected to the die pad 20. In the semiconductor device A10, the first electrode 11 is conductively bonded to each of the mounting surface 201 of the first portion 20A of the die pad 20 and the mounting surface 201 of the second portion 20B of the die pad 20. The conductive bonding layer 29 is solder, for example. Alternatively, the conductive bonding layer 29 may be sintered body of metal particles.

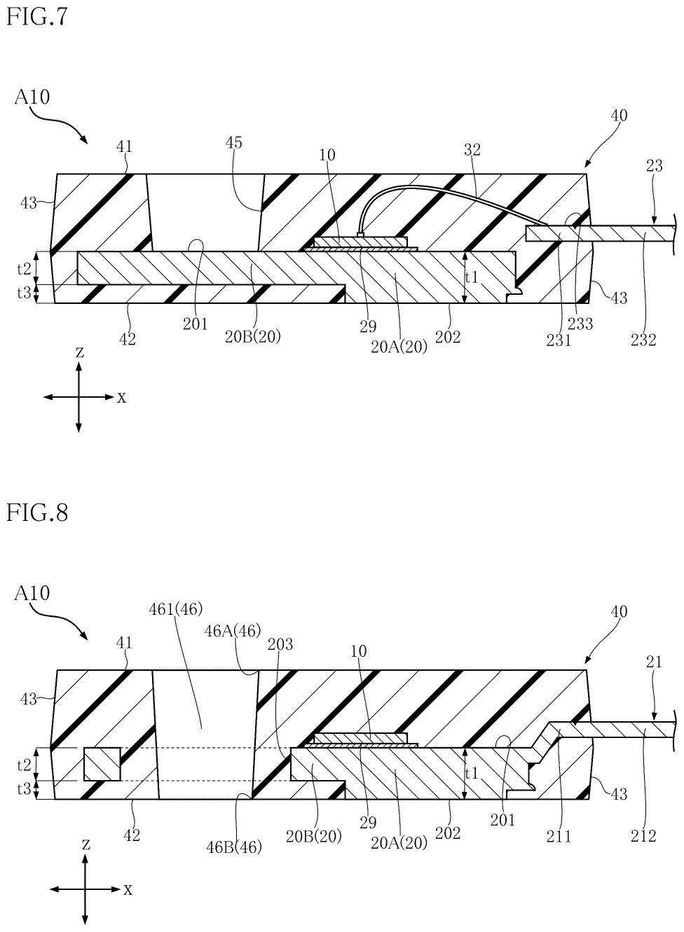

As shown in FIGS. 3 and 8, the first lead 21 includes a portion extending in the second direction x and is connected to the first portion 20A of the die pad 20. The first lead 21 is thereby electrically connected to the first electrode 11 of the semiconductor element 10. Hence, the first lead 21 corresponds to a drain terminal of the semiconductor device A10. The first lead 21 is located opposite to the second portion 20B of the die pad 20 with respect to the first portion 20A in the second direction x.

As shown in FIGS. 3 and 8, the first lead 21 includes a covered portion 211 and an exposed portion 212. The covered portion 211 is connected to the first portion 20A of the die pad 20 and is covered with the sealing resin 40. As viewed in the third direction y, the covered portion 211 is bent. The exposed portion 212 is connected to the covered portion 211 and is exposed from the sealing resin 40. The exposed portion 212 protrudes from the sealing resin 40 on the side opposite to the die pad 20 in the second direction x. The surface of the exposed portion 212 is plated with tin, for example.

As shown in FIGS. 3 and 6, the second lead 22 is spaced apart from the die pad 20. The second lead 22 extends along the second direction x. The second lead 22 is electrically connected to the second electrode 12 of the semiconductor element 10. Hence, the second lead 22 corresponds to a source terminal of the semiconductor device A10. The second lead 22 is located next to the first lead 21 in the third direction y.

As shown in FIGS. 3 and 6, the second lead 22 includes a covered portion 221, an exposed portion 222, and a first bonding surface 223. The covered portion 221 is covered with the sealing resin 40. The exposed portion 222 is connected to the covered portion 221 and is exposed from the sealing resin 40. The exposed portion 222 protrudes from the sealing resin 40 on the side opposite to the die pad 20 in the second direction x. The surface of the exposed portion 222 is plated with tin, for example. The first bonding surface 223 faces the same side as the mounting surface 201 of the die pad 20 in the first direction z. The first bonding surface 223 is a part of the covered portion 221. The first bonding surface 223 is located closer to the semiconductor element 10 than the mounting surface 201 in the first direction z.

As shown in FIGS. 3 and 7, the third lead 23 is spaced apart from the die pad 20. The third lead 23 extends along the second direction x. The third lead 23 is electrically connected to the gate electrode 13 of the semiconductor element 10. Hence, the third lead 23 corresponds to a gate terminal of the semiconductor device A10. The third lead 23 is located the side opposite to the second lead 22 with respect to the first lead 21 in the third direction y.

As shown in FIGS. 3 and 7, the third lead 23 includes a covered portion 231, an exposed portion 232, and a second bonding surface 233. The covered portion 231 is covered with the sealing resin 40. The exposed portion 232 is connected to the covered portion 231 and is exposed from the sealing resin 40. The exposed portion 232 protrudes from the sealing resin 40 on the side opposite to the die pad 20 in the second direction x. The surface of the exposed portion 232 is plated with tin, for example. The second bonding surface 233 faces the same side as the mounting surface 201 of the die pad 20 in the first direction z. The second bonding surface 233 is a part of the covered portion 231. In the first direction z, the position of the second bonding surface 233 is the same (or is generally the same) as the position of the first bonding surface 223 of the second lead 22.

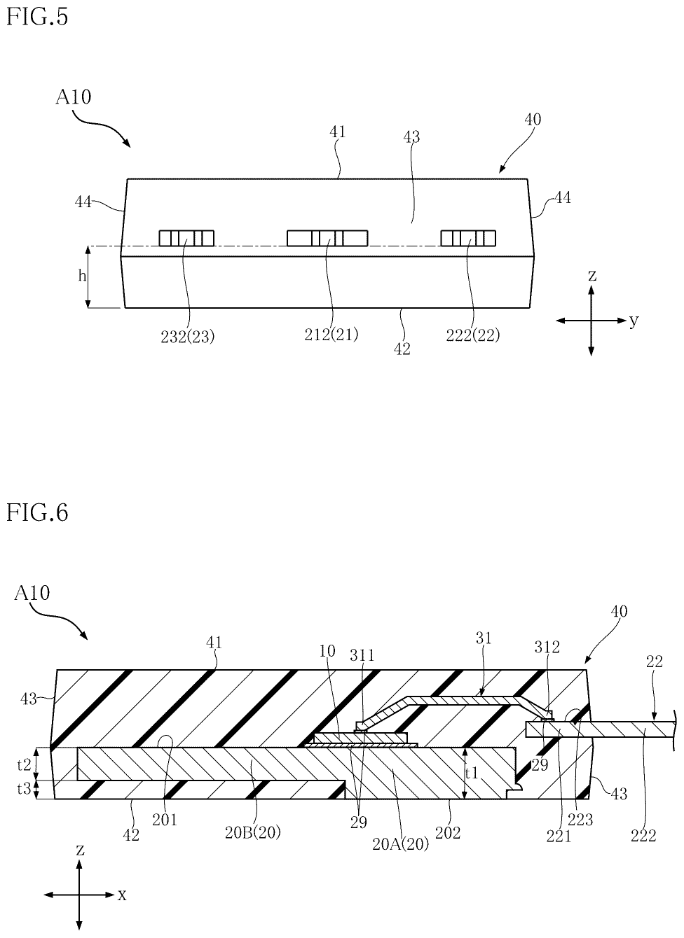

As shown in FIG. 3, the first lead 21, the second lead 22, and the third lead 23 are arranged along the third direction y. As shown in FIG. 5, the exposed portion 212 of the first lead 21, the exposed portion 222 of the second lead 22, and the exposed portion 232 of the third lead 23 each have the same height h from a bottom surface 42, which is described hereinafter, of the sealing resin 40.

As shown in FIGS. 3 and 6, the conductive member 31 is conductively bonded to the second electrode 12 of the semiconductor element 10 and the first bonding surface 223 of the second lead 22. Hence, the second lead 22 is electrically connected to the second electrode 12. The conductive member 31 contains copper or a copper alloy. The conductive member 31 is a metal clip. Alternatively, the conductive member 31 may be a wire. As shown in FIG. 6, the conductive member 31 includes a first bonding portion 311 and a second bonding portion 312. The first bonding portion 311 is one end of the conductive member 31 and is conductively bonded to the second electrode 12 via the conductive bonding layer 29. The second bonding portion 312 is another end of the conductive member 31 and is conductively bonded to the first bonding surface 223 via the conductive bonding layer 29.

As shown in FIGS. 3 and 7, the wire 32 is conductively bonded to the gate electrode 13 of the semiconductor element 10 and the second bonding surface 233 of the third lead 23. Hence, the third lead 23 is electrically connected to the gate electrode 13. The wire 32 contains, for example, either aluminum or gold (Au).

As shown in FIGS. 3, 6, and 7, the sealing resin 40 covers the semiconductor element 10, the conductive member 31, and the wire 32. As shown in FIGS. 6 to 8, the sealing resin 40 covers a part of each of the die pad 20, the first lead 21, the second lead 22, and the third lead 23. The sealing resin 40 has electrical insulating properties. The sealing resin 40 is made of a material including a black epoxy resin, for example. The sealing resin 40 has a top surface 41, a bottom surface 42, two first side surfaces 43, two second side surfaces 44, and two openings 45.

As shown in FIGS. 6 to 8, the top surface 41 faces the same side as the mounting surface 201 of the die pad 20 in the first direction z. As shown in FIGS. 6 to 8, the bottom surface 42 faces the side opposite to the top surface 41 in the first direction z. From the bottom surface 42 is exposed the reverse surface 202 of the first portion 20A of the die pad 20.

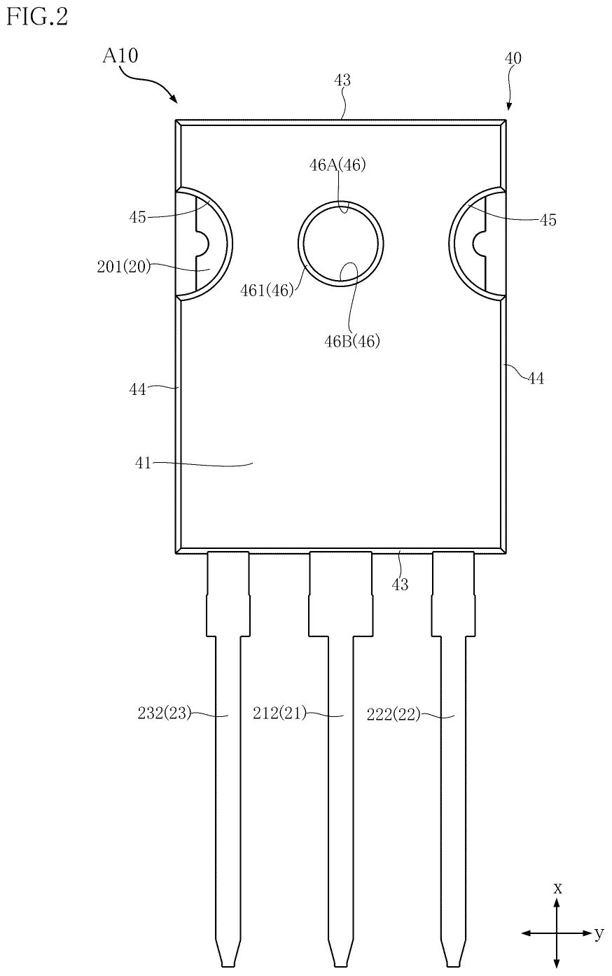

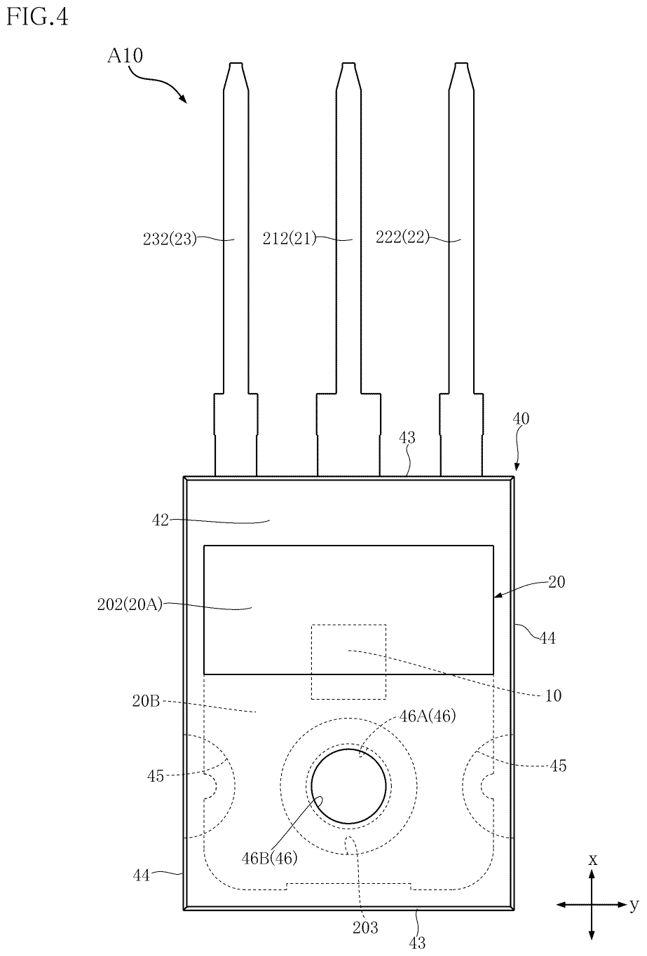

As shown in FIGS. 2 and 4, the two first side surfaces 43 are spaced apart from each other in the second direction x. Each of the two first side surfaces 43 is connected to the top surface 41 and the bottom surface 42. From one of the two first side surfaces 43 protrudes each of the exposed portion 212 of the first lead 21, the exposed portion 222 of the second lead 22, and the exposed portion 232 of the third lead 23 in the second direction x.

As shown in FIGS. 2 and 4, the two second side surfaces 44 are spaced apart from each other in the third direction y. Each of the two second side surfaces 44 is connected to the top surface 41 and the bottom surface 42. As shown in FIG. 2, the two openings 45 are spaced apart from each other in the third direction y. Each of the two openings 45 is recessed inwardly of the sealing resin 40 from the top surface 41 and one of the two second side surfaces 44. From each of the two openings 45 is exposed a part of the mounting surface 201 of the second portion 20B of the die pad 20.

As shown in FIGS. 2, 4 and 8, the sealing resin 40 has an attachment portion 46 that penetrates in the first direction z from the top surface 41 to the bottom surface 42. As shown in FIG. 3, the attachment portion 46 is surrounded by the penetration portion 203 of the second portion 20B of the die pad 20, as viewed in the first direction z. In other words, the attachment portion 46 is located inside the penetration portion 203, as viewed in the first direction z.

As shown in FIGS. 2 and 8, the sealing resin 40 has an inner circumferential surface 461 that is connected to the top surface 41 and bottom surface 42 and defines the attachment portion 46. The attachment portion 46 includes a first hole edge 46A, which is the boundary between the inner circumferential surface 461 and the top surface 41, and a second hole edge 46B, which is the boundary between the inner circumferential surface 461 and the bottom surface 42. As shown in FIGS. 2 and 4, the first hole edge 46A surrounds the second hole edge 46B as viewed in the first direction z.

As shown in FIGS. 6 to 8, the second dimension t2 in the first direction z of the second portion 20B of the die pad 20 is different from a third dimension t3 in the first direction z of the part of the sealing resin 40 from the bottom surface 42 to the second portion 20B. The second dimension t2 is greater than the third dimension t3.

Next, operative effects of the semiconductor device A10 will be described.

The semiconductor device A10 includes the die pad 20 having the penetration portion 203 that penetrates in the first direction z, the semiconductor element 10 bonded to the die pad 20, and the sealing resin 40 that covers the semiconductor element 10 and has the attachment portion 46 penetrating in the first direction z. The attachment portion 46 is surrounded by the penetration portion 203 as viewed in the first direction z. The die pad 20 includes the first portion 20A with the reverse surface 202 and the second portion 20B with the penetration portion 203. The second portion 20B is offset on the one side of the second direction x with respect to the first portion 20A. The reverse surface 202 is exposed from the sealing resin 40. The second portion 20B is covered with the sealing resin 40. According to such a configuration, the entirety of the reverse surface 202 exposed from the sealing resin 40 is farther away from the attachment portion 46 on the one side of the second direction x. Hence, when the semiconductor device A10 is attached to a heat sink by inserting a fastening member such as a bolt into the attachment portion 46, the creepage distance from the fastening member to the reverse surface 202 is increased. Therefore, such a configuration improves the insulation withstand voltage while suppressing a reduction in heat dissipation of the semiconductor device A10.

The first dimension t1 in the first direction z of the first portion 20A is greater than the second dimension t2 in the first direction z of the second portion 20B. Such a configuration results in the second portion 20B being sandwiched by the sealing resin 40 in the first direction z. This prevents the die pad 20 from the detachment of the sealing resin 40.

The die pad 20 has the mounting surface 201 facing the side opposite to the reverse surface 202 in the first direction z. Each of the first portion 20A and the second portion 20B has the mounting surface 201. The semiconductor element 10 is conductively bonded to each of the mounting surface 201 of the first portion 20A and the mounting surface 201 of the second portion 20B. Such a configuration can provide a sufficient area of the mounting surface 201 to which the semiconductor element 10 is conductively bonded, even when the area of the reverse surface 202 is reduced within a range that does not cause a significant reduction in heat dissipation.

The dimension in the second direction x of the second portion 20B is greater than the dimension in the second direction x of the reverse surface 202 of the first portion 20A. Such a configuration can increase the creepage distance from the attachment portion 46 of the sealing resin 40 to the reverse surface 202 while sufficiently ensuring the area of the mounting surface 201 of the die pad 20 to which the semiconductor element 10 is conductively bonded.

The second dimension t2 in the first direction z of the second portion 20B is greater than the third dimension t3 in the first direction z of the part of the sealing resin 40 from the bottom surface 42 to the second portion 20B. Such a configuration can reduce the thermal resistance in the first direction z of the second portion 20B. This makes it possible to improve the heat dissipation of the semiconductor device A10.

The sealing resin 40 has the inner circumferential surface 461 that is connected to each of the top surface 41 and bottom surface 42 and defines an attachment portion 46. The attachment portion 46 includes the first hole edge 46A, which is the boundary between the inner circumferential surface 461 and the top surface 41, and the second hole edge 46B, which is the boundary between the inner circumferential surface 461 and the bottom surface 42. The first hole edge 46A surrounds the second hole edge 46B as viewed in the first direction z. Such a configuration can enhance releasability of the mold from the attachment portion 46 when the sealing resin 40 is formed in manufacturing the semiconductor device A10. This prevents failure of the attachment portion 46.

### Second Embodiment

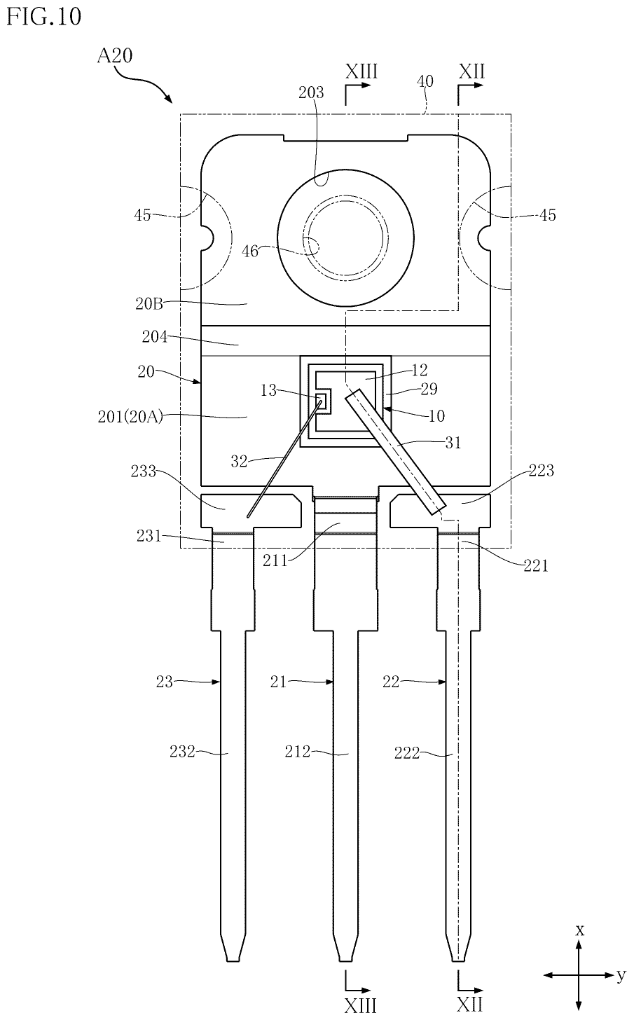

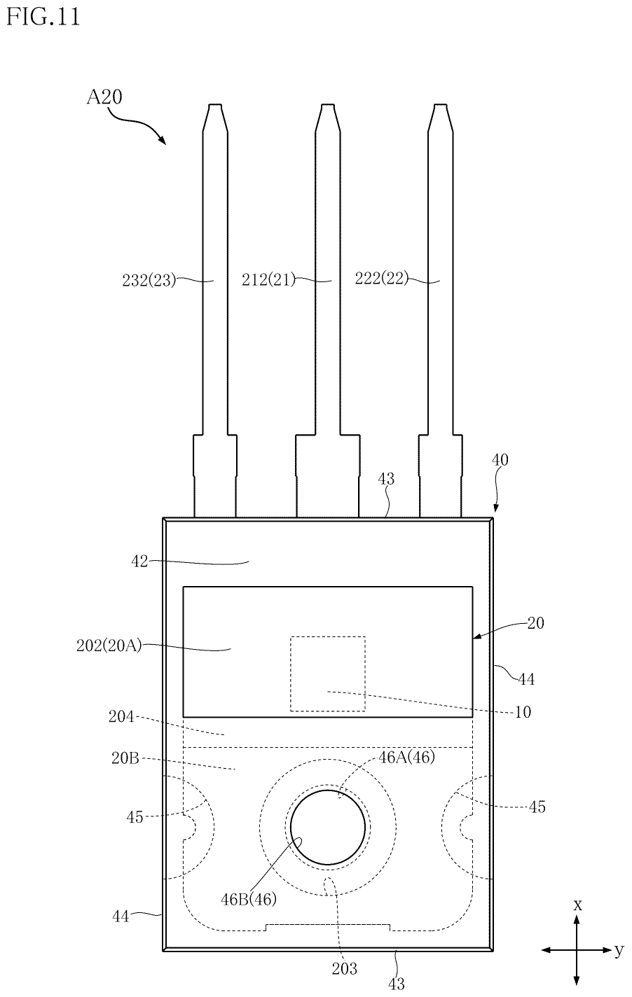

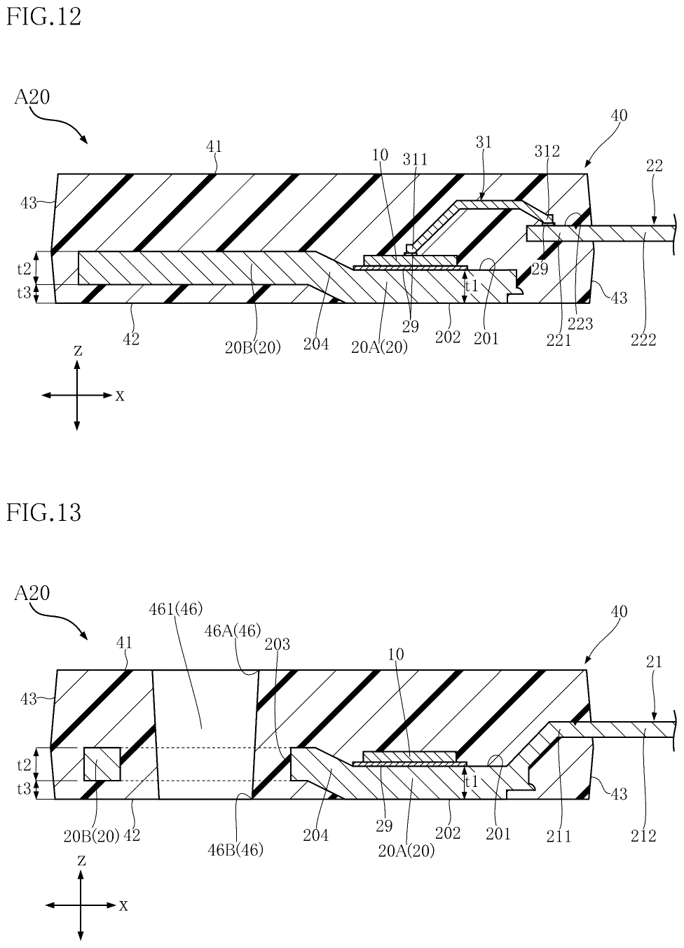

Based on FIGS. 10 to 13, a semiconductor device A20 according to a second embodiment of the present disclosure is described. In these figures, the same or similar elements as those of the semiconductor device A10 described above are denoted by the same reference signs, and overlapping descriptions are omitted. For convenience of understanding, in FIG. 10, the sealing resin 40 is shown as transparent. In FIG. 10, the transparent sealing resin 40 is shown as imaginary lines (double-dotted lines).

The semiconductor device A20 differs from the semiconductor device A10 in the configuration of the die pad 20.

As shown in FIGS. 10 to 13, the second portion 20B of the die pad 20 includes a bent portion 204. The bent portion 204 is located on the one side of the second direction x in the second portion 20B and extends along the third direction y. The second portion 20B is connected to the first portion 20A of the die pad 20 through the bent portion 204. The bent portion 204 is bent as viewed in the third direction y.

In the semiconductor device A20, the second portion 20B of the die pad 20 does not include the mounting surface 201. Therefore, the semiconductor element 10 is conductively bonded only to the first portion 20A of the die pad 20. Further, in the semiconductor device A20, the first dimension t1 in the first direction z of the first portion 20A is equal to the second dimension t2 in the first direction z of the second portion 20B (but excluding the bent portion 204).

Next, operative effects of the semiconductor device A20 will be described.

The semiconductor device A20 includes the die pad 20 having the penetration portion 203 that penetrates in the first direction z, the semiconductor element 10 bonded to the die pad 20, and the sealing resin 40 that covers the semiconductor element 10 and has the attachment portion 46 penetrating in the first direction z. The attachment portion 46 is surrounded by the penetration portion 203 as viewed in the first direction z. The die pad 20 includes the first portion 20A with the reverse surface 202 and the second portion 20B with the penetration portion 203. The second portion 20B is offset on the one side of the second direction x with respect to the first portion 20A. The reverse surface 202 is exposed from the sealing resin 40. The second portion 20B is covered with the sealing resin 40. Hence, such a configuration improves the insulation withstand voltage while suppressing a reduction in heat dissipation of the semiconductor device A20. In addition, the semiconductor device A20 may have a configuration in common with the semiconductor device A10, thereby achieving the same effect as the semiconductor device A10.

### Third Embodiment

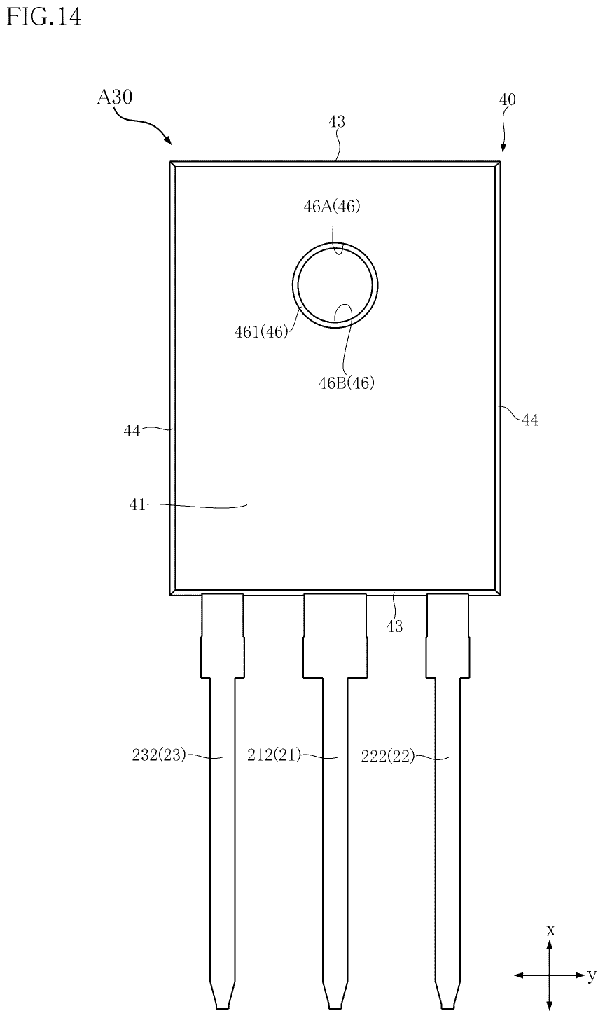

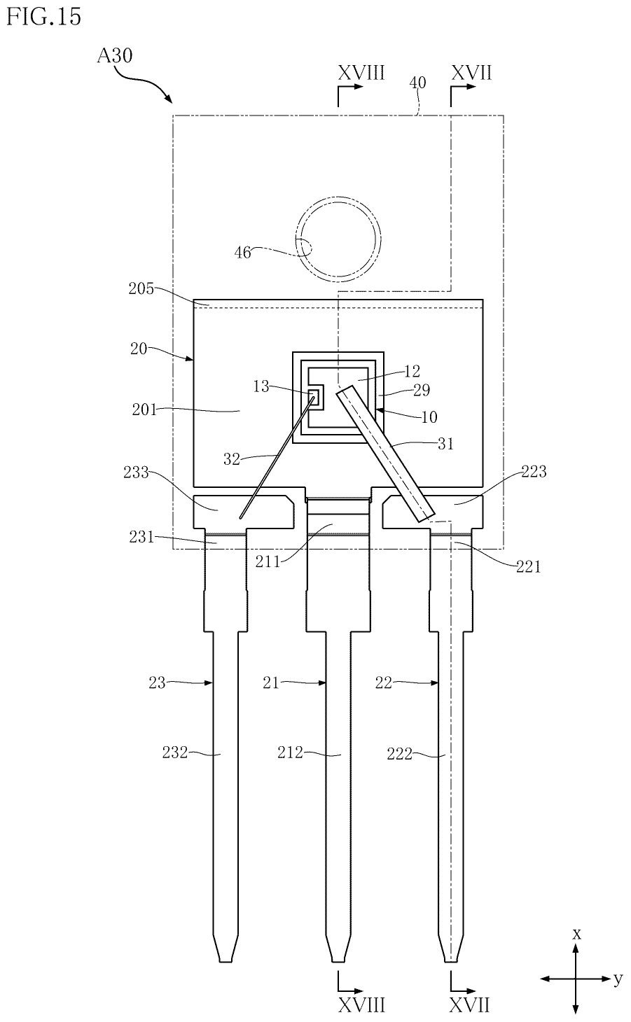

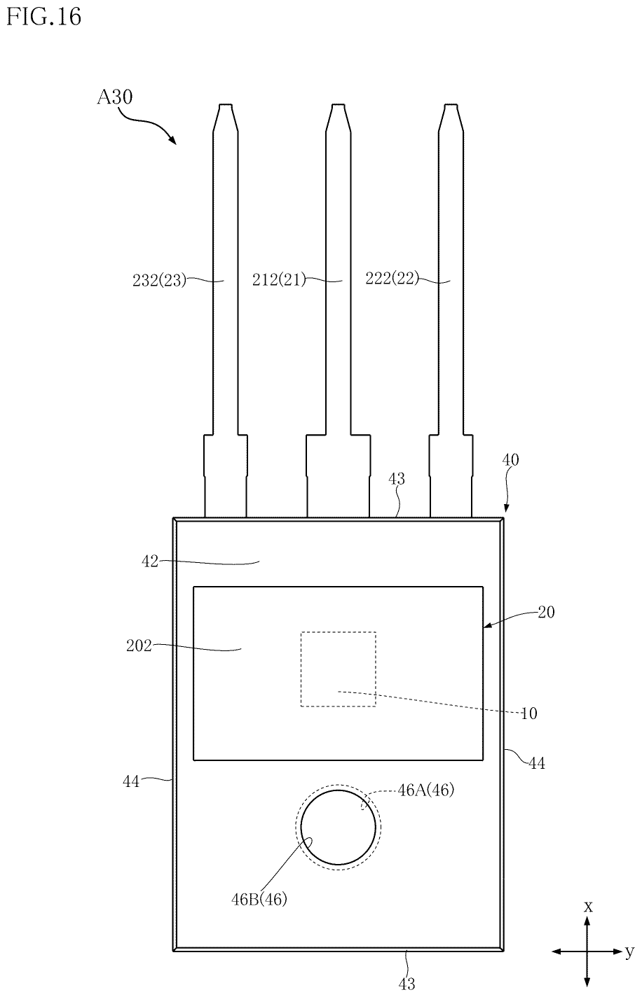

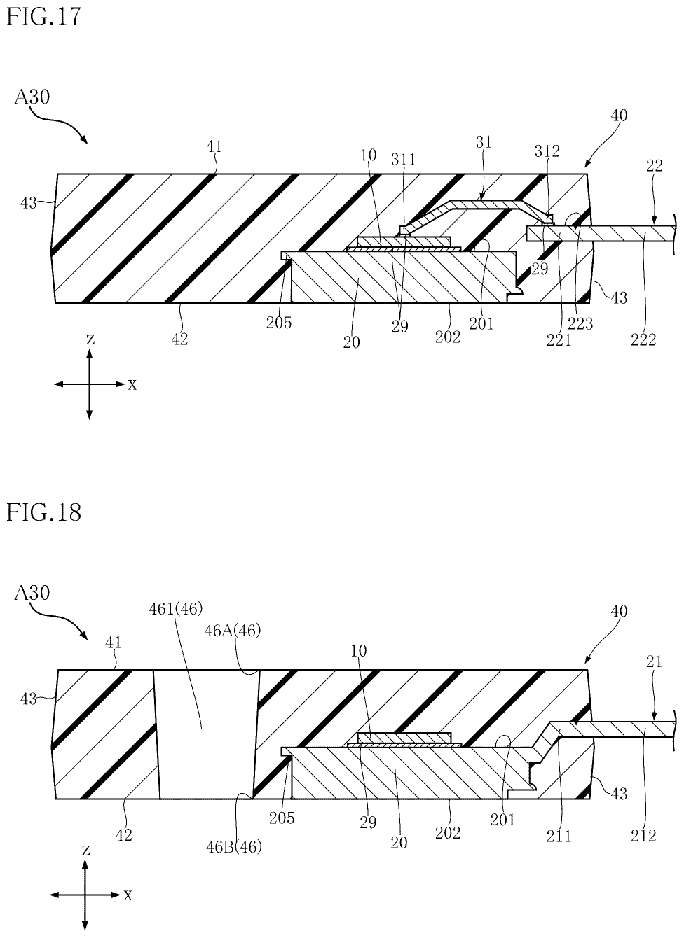

Based on FIGS. 14 to 18, a semiconductor device A30 according to a third embodiment of the present disclosure is described. In these figures, the same or similar elements as those of the semiconductor device A10 described above are denoted by the same reference signs, and overlapping descriptions are omitted. For convenience of understanding, in FIG. 15, the sealing resin 40 is shown as transparent. In FIG. 15, the transparent sealing resin 40 is shown as imaginary lines (double-dotted lines).

The semiconductor device A30 differs from the semiconductor device A10 in the configuration of the die pad 20 and the sealing resin 40.

As shown in FIGS. 15 to 18, the die pad 20 does not includes the first portion 20A and the second portion 20B. Further, the die pad 20 is not provided with the penetration portion 203. The die pad 20 has the mounting surface 201, the reverse surface 202, and an eaves portion 205. The eaves portion 205 is flush with the mounting surface 201 in the first direction z. The eaves portion 205 is located opposite to the first lead 21 in the second direction x. The eaves portion 205 extends along the third direction y. The eaves portion 205 is sandwiched by the sealing resin 40 in the first direction z.

As shown in FIGS. 15 to 18, the entirety of the die pad 20 is offset on the one side of the second direction x with respect to the attachment portion 46 of the sealing resin 40.

As shown in FIG. 14, the sealing resin 40 does not include the two openings 45. Therefore, in the die pad 20, only the reverse surface 202 is exposed from the sealing resin 40.

Next, operative effects of the semiconductor device A30 will be described.

The semiconductor device A30 includes the die pad 20 having the reverse surface 202 facing the first direction z, the semiconductor element 10 bonded to the die pad 20, and the sealing resin 40 that covers the semiconductor element 10 and has the attachment portion 46 penetrating in the first direction z. The entirety of the die pad 20 is offset on the one side of the second direction x with respect to the attachment portion 46. The reverse surface 202 is exposed from the sealing resin 40. According to such a configuration, the entirety of the reverse surface 202 exposed from the sealing resin 40 is away from the attachment portion 46 on the one side of the second direction x, as with the semiconductor device A10. Hence, such a configuration improves the insulation withstand voltage while suppressing a reduction in heat dissipation of the semiconductor device A30. In addition, the semiconductor device A30 may have a configuration in common with the semiconductor device A10, thereby achieving the same effect as the semiconductor device A10.

The present disclosure is not limited to the embodiments described above. The specific configuration of each part of the present disclosure may suitably be designed and changed in various manners.

The present disclosure includes the embodiments described in the following clauses.

### Clause 1

A semiconductor device comprising:
a die pad having a penetration portion that penetrates in a first direction;
a semiconductor element bonded to the die pad; and
a sealing resin covering the semiconductor element, the sealing resin having an attachment portion that penetrates in the first direction and is surrounded by the penetration portion as viewed in the first direction,
wherein the die pad includes a first portion having a reverse surface that faces the first direction, and a second portion having the penetration portion and connected to the first portion,
the second portion is offset on one side of a second direction orthogonal to the first direction with respect to the first portion,
the reverse surface is exposed from the sealing resin, and
the second portion is covered with the sealing resin.

### Clause 2

The semiconductor device according to clause 1, wherein a first dimension in the first direction of the first portion is greater than a second dimension in the first direction of the second portion.

### Clause 3

The semiconductor device according to clause 2, wherein the sealing resin has a bottom surface facing the same side as the reverse surface in the first direction, and
the reverse surface is exposed from the bottom surface.

### Clause 4

The semiconductor device according to clause 3, wherein the die pad has a mounting surface facing a side opposite to the reverse surface in the first direction,
each of the first portion and the second portion includes the mounting surface, and
the semiconductor element is bonded to the mounting surface.

### Clause 5

The semiconductor device according to clause 4, 5. The semiconductor device according to claim 4, wherein the semiconductor element is conductively bonded to the mounting surface.

### Clause 6

The semiconductor device according to clause 5, wherein a dimension in the second direction of the second portion is greater than a dimension in the second direction of the reverse surface.

### Clause 7

The semiconductor device according to clause 6, wherein the semiconductor element is conductively bonded to each of the mounting surface of the first portion and the mounting surface of the second portion.

### Clause 8

The semiconductor device according to clause 4, wherein the second dimension is different from a third dimension in the first direction of a part of the sealing resin from the bottom surface to the second portion.

### Clause 9

The semiconductor device according to clause 8, wherein the second dimension is greater than the third dimension.

### Clause 10

The semiconductor device according to any one of clauses 5 to 9, further comprising a first lead,
wherein the semiconductor element includes a first electrode facing the mounting surface in the first direction,
the first electrode is conductively bonded to the mounting surface, and
the first lead is electrically connected to the first electrode.

### Clause 11

The semiconductor device according to clause 10, wherein the first lead is connected to the first portion.

### Clause 12

The semiconductor device according to clause 11, wherein the first lead is located opposite to the second portion with respect to the first portion in the second direction.

### Clause 13

The semiconductor device according to clause 12, further comprising a second lead,
wherein the semiconductor element includes a second electrode located on a side opposite to the first electrode in the first direction,
the second lead is electrically connected to the second electrode, and
the second lead is located next to the first lead in a third direction orthogonal to the first direction and the second direction.

### Clause 14

The semiconductor device according to clause 13, further comprising a third lead,
wherein the semiconductor element includes a gate electrode located on the same side as the second electrode in the first direction,
the third lead is electrically connected to the gate electrode, and
the third lead is located on a side opposite to the second lead with respect to the first lead in the third direction.

### Clause 15

The semiconductor device according to clause 14, wherein each of the first lead, the second lead, and the third lead includes a portion protruding from the sealing resin on a side opposite to the die pad in the second direction.

### Clause 16

The semiconductor device according to clause 15, wherein the sealing resin has a top surface facing a side opposite to the bottom surface in the first direction, and an inner circumferential surface connected to the top surface and the bottom surface and defining the attachment portion,
the attachment portion includes a first hole edge, which is a boundary between the inner circumferential surface and the top surface, and a second hole edge, which is a boundary between the inner circumferential surface and the bottom surface, and
the first hole edge surrounds the second hole edge as viewed in the first direction.

### Clause 17

A semiconductor device comprising:
a die pad having a reverse surface facing a first direction;
a semiconductor element bonded to the die pad; and
a sealing resin covering the semiconductor element, the sealing resin having an attachment portion that penetrates in the first direction,
wherein an entirety of the die pad is offset on the one side of a second direction orthogonal to the first direction with respect to the attachment portion, and
the reverse surface is exposed from the sealing resin.

### REFERENCE NUMERALS

A10, A20, A30: Semiconductor device 10: Semiconductor element
11: First electrode 12: Second electrode 13: Gate electrode
20: Die pad 20A: First portion 20B: Second portion
201: Mounting surface 202: Reverse surface 203: Penetration portion
204: Bent portion 205: Eaves portion 21: First lead
211: Covered portion 212: Exposed portion 22: Second lead
221: Covered portion 222: Exposed portion 223: First bonding surface
23: Third lead 231: Covered portion 232: Exposed portion
233: Second bonding surface 29: Conductive bonding layer
31: Conductive member 311: First bonding portion
312: Second bonding portion 32: Wire
40: Sealing resin 41: Top surface 42: Bottom surface
43: First side face 44: Second side face 45: Opening
46: Attachment portion 461: Inner circumferential surface
46A: First hole edge 46B: Second hole edge
z: first direction x: second direction y: third direction

1. A semiconductor device comprising:
a die pad having a penetration portion that penetrates in a first direction;
a semiconductor element bonded to the die pad; and
a sealing resin covering the semiconductor element, the sealing resin having an attachment portion that penetrates in the first direction and is surrounded by the penetration portion as viewed in the first direction,
wherein the die pad includes a first portion having a reverse surface that faces the first direction, and a second portion having the penetration portion and connected to the first portion,
the second portion is offset on one side of a second direction orthogonal to the first direction with respect to the first portion,
the reverse surface is exposed from the sealing resin, and
the second portion is covered with the sealing resin.

2. The semiconductor device according to claim 1, wherein a first dimension in the first direction of the first portion is greater than a second dimension in the first direction of the second portion.

3. The semiconductor device according to claim 2, wherein the sealing resin has a bottom surface facing the same side as the reverse surface in the first direction, and
the reverse surface is exposed from the bottom surface.

4. The semiconductor device according to claim 3, wherein the die pad has a mounting surface facing a side opposite to the reverse surface in the first direction,
each of the first portion and the second portion includes the mounting surface, and
the semiconductor element is bonded to the mounting surface.

5. The semiconductor device according to claim 4, wherein the semiconductor element is conductively bonded to the mounting surface.

6. The semiconductor device according to claim 5, wherein a dimension in the second direction of the second portion is greater than a dimension in the second direction of the reverse surface.

7. The semiconductor device according to claim 6, wherein the semiconductor element is conductively bonded to each of the mounting surface of the first portion and the mounting surface of the second portion.

8. The semiconductor device according to claim 4, wherein the second dimension is different from a third dimension in the first direction of a part of the sealing resin from the bottom surface to the second portion.

9. The semiconductor device according to claim 8, wherein the second dimension is greater than the third dimension.

10. The semiconductor device according to claim 5, further comprising a first lead,
wherein the semiconductor element includes a first electrode facing the mounting surface in the first direction,
the first electrode is conductively bonded to the mounting surface, and
the first lead is electrically connected to the first electrode.

11. The semiconductor device according to claim 10, wherein the first lead is connected to the first portion.

12. The semiconductor device according to claim 11, wherein the first lead is located on a side opposite to the second portion with respect to the first portion in the second direction.

13. The semiconductor device according to claim 12, further comprising a second lead,
wherein the semiconductor element includes a second electrode located on a side opposite to the first electrode in the first direction,
the second lead is electrically connected to the second electrode, and
the second lead is located next to the first lead in a third direction orthogonal to the first direction and the second direction.

14. The semiconductor device according to claim 13, further comprising a third lead,
wherein the semiconductor element includes a gate electrode located on the same side as the second electrode in the first direction,
the third lead is electrically connected to the gate electrode, and
the third lead is located on a side opposite to the second lead with respect to the first lead in the third direction.

15. The semiconductor device according to claim 14, wherein each of the first lead, the second lead, and the third lead includes a portion protruding from the sealing resin on a side opposite to the die pad in the second direction.

16. The semiconductor device according to claim 15, wherein the sealing resin has a top surface facing a side opposite to the bottom surface in the first direction, and an inner circumferential surface connected to the top surface and the bottom surface and defining the attachment portion,
the attachment portion includes a first hole edge, which is a boundary between the inner circumferential surface and the top surface, and a second hole edge, which is a boundary between the inner circumferential surface and the bottom surface, and
the first hole edge surrounds the second hole edge as viewed in the first direction.

17. A semiconductor device comprising:
a die pad having a reverse surface facing a first direction;
a semiconductor element bonded to the die pad; and
a sealing resin covering the semiconductor element, the sealing resin having an attachment portion that penetrates in the first direction,
wherein an entirety of the die pad is offset on the one side of a second direction orthogonal to the first direction with respect to the attachment portion, and
the reverse surface is exposed from the sealing resin.
